(19) United States
(12) Patent Application Publication
(10) Pub. No.: US 2026/0026060 A1
(43) Pub. Date: Jan. 22, 2026

(54) SEMICONDUCTOR DEVICE

(71) Applicant: Samsung Electronics Co., Ltd., Suwon-si (KR)

(72) Inventors: JIN-HWAN KIM, Suwon-si (KR); IN JUN HWANG, Suwon-si (KR)

(21) Appl. No.: 19/043,392

(22) Filed: Jan. 31, 2025

(30) Foreign Application Priority Data
Jul. 22, 2024 (KR) 10-2024-0096440

(51) Int. Cl. H10D 62/815; H10D 30/47; H10D 62/85

(52) U.S. Cl. CPC H10D 62/815; H10D 30/472; H10D 62/8503

(57) ABSTRACT

A semiconductor device may include a substrate, a first transistor and a second transistor positioned on the substrate, a buffer layer disposed between the first transistor and the substrate and between the second transistor and the substrate, a well region positioned within the buffer layer, and an insulating pattern extending through the well region. Each of the first and second transistors may include a channel layer disposed on the substrate, a barrier layer disposed on a corresponding channel layer, a gate electrode positioned on a corresponding barrier layer, and a source electrode and a drain electrode positioned at opposite sides of a corresponding gate electrode and connected to a corresponding channel layer. The source electrode of the first transistor and the drain electrode of the second transistor are connected to the well region.

### CROSS-REFERENCE TO RELATED APPLICATION(S)

This application claims priority to and the benefit of Korean Patent Application No. 10-2024-0096440, filed in the Korean Intellectual Property Office on Jul. 22, 2024, the disclosure of which is incorporated herein by reference in its entirety.

### BACKGROUND

### 1. Field

The present disclosure relates to a semiconductor device.

### 2. Description of the Related Art

In modern society, semiconductor devices are closely related to daily life. In particular, the importance of power semiconductor devices is gradually increasing in various fields, e.g., transportation such as electric vehicles, railways, and electric trams, renewable energy systems such as solar and wind power generation, and mobile devices. Power semiconductor devices are semiconductor devices used to handle high voltage or high current, and perform functions such as power conversion and control in large power systems or high-output electronic devices. The power semiconductor devices have ability and durability to handle high power, so they may handle large amounts of current and withstand high voltage. For example, the power semiconductor devices may handle voltages from hundreds of volts to thousands of volts and currents from tens of amperes to thousands of amperes. The power semiconductor devices may improve the efficiency of electrical energy by minimizing power loss. Additionally, the power semiconductor devices may be stably driven even in environments such as high temperatures.

These power semiconductor devices may be classified according to materials, and examples thereof include SiC power semiconductor devices and GaN power semiconductor devices. The disadvantage of silicon, which has unstable characteristics at high temperatures, may be compensated by manufacturing the power semiconductor devices using SiC or GaN instead of existing silicon (Si). SiC power semiconductor devices may be resistant to high temperatures and have low power loss, and may be suitable for electric vehicles, renewable energy systems, etc. GaN power semiconductor devices may require high costs, but may be efficient in terms of speed, and may be suitable for high-speed charging of mobile devices.

### SUMMARY

Embodiments attempts to provide a semiconductor device including two high electron mobility transistors connected in series on one substrate between a first power voltage and a second power voltage that is lower than the first power voltage.

An embodiment of the present disclosure provides a semiconductor device including: a substrate; a first transistor and a second transistor positioned on the substrate; a buffer layer disposed between the first transistor and the substrate and between the second transistor and the substrate; a well region positioned within the buffer layer; and an insulating pattern extending through the well region. The first transistor includes: a first channel layer disposed on the substrate; a first barrier layer disposed on the first channel layer; a first gate electrode positioned on the first barrier layer; and a first source electrode and a first drain electrode positioned at opposite sides of the first gate electrode and connected to the first channel layer. The second transistor includes: a second channel layer disposed on the substrate; a second barrier layer disposed on the second channel layer; a second gate electrode positioned on the second barrier layer; and a second source electrode and a second drain electrode positioned at opposite sides of the second gate electrode and connected to the second channel layer. The first drain electrode is connected to a first power voltage, and the second source electrode is connected to a second power voltage different from the first power voltage, and the first source electrode and the second drain electrode are connected to the well region.

An embodiment of the present disclosure provides a semiconductor device including: a substrate; a buffer layer disposed on the substrate; an insulating pattern extending through at least a portion of the buffer layer; and a first well region and a second well region positioned within the buffer layer and spaced apart by the insulating pattern, and a first transistor positioned on the first well region and a second transistor positioned on the second well region. The first transistor includes: a first channel layer disposed on the substrate; a first barrier layer disposed on the first channel layer; a first gate electrode positioned on the first barrier layer; and a first source electrode and a first drain electrode positioned at opposite sides of the first gate electrode and connected to the first channel layer. The second transistor includes: a second channel layer disposed on the substrate; a second barrier layer disposed on the second channel layer; a second gate electrode positioned on the second barrier layer; and a second source electrode and a second drain electrode positioned at opposite sides of the second gate electrode and connected to the second channel layer. The first drain electrode is connected to a first power voltage, and the second source electrode is connected to a second power voltage, and the first source electrode and the second drain electrode are connected to the first well region.

An embodiment of the present disclosure provides a semiconductor device including: a substrate; a first transistor and a second transistor positioned on the substrate; a buffer layer disposed between the first transistor and the substrate and between the second transistor and the substrate; a well region positioned within the buffer layer and including GaN doped with an n-type impurity; and an insulating pattern extending through the well region. The first transistor includes: a first channel layer disposed on the substrate and including GaN; a first barrier layer disposed on the first channel layer and including AlGaN; a first gate electrode positioned on the first barrier layer; and a first source electrode and a first drain electrode positioned at opposite sides of the first gate electrode and connected to the first channel layer. The second transistor includes: a second channel layer disposed on the substrate and including GaN; a second barrier layer disposed on the second channel layer and including AlGaN; a second gate electrode positioned on the second barrier layer; and a second source electrode and a second drain electrode positioned at opposite sides of the second gate electrode and connected to the second channel layer. The first drain electrode is connected to a first power voltage, and the second source electrode is connected to a second power voltage that is lower than the first power voltage, and the first source electrode and the second drain electrode are connected to the well region.

According to the embodiments, it may be possible to form two high electron mobility transistors connected in series on one substrate between a first power voltage and a second power voltage that is lower than the first power voltage.

### BRIEF DESCRIPTION OF THE DRAWINGS

FIG. 1 illustrates a circuit diagram of a semiconductor device according to an embodiment.

FIG. 2 illustrates a cross-sectional view showing a high electron mobility transistor (HEMT) of a semiconductor device according to an embodiment.

FIG. 3 illustrates a top plan view showing an amplification circuit of a semiconductor device according to an embodiment.

FIG. 4 illustrates a cross-sectional view taken along line I-I′ according to an embodiment.

FIG. 5 illustrates a cross-sectional view showing an amplification circuit of a semiconductor device according to an embodiment.

FIG. 6 illustrates a top plan view showing an amplification circuit of a semiconductor device according to an embodiment.

FIG. 7 illustrates a cross-sectional view taken along a line II-II′ of FIG. 6 according to an embodiment.

FIG. 8 illustrates a top plan view showing an amplification circuit of a semiconductor device according to an embodiment.

FIG. 9 illustrates a cross-sectional view taken along a line III-III′ of FIG. 8 according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present invention is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

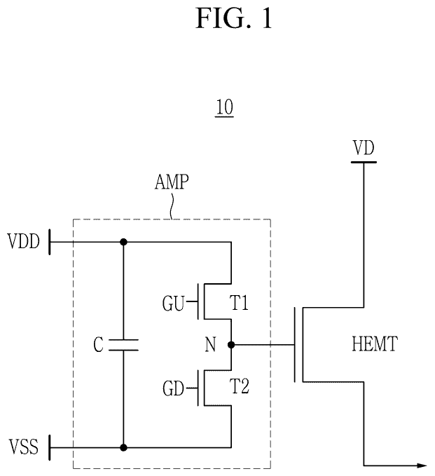

Hereinafter, a semiconductor device according to an embodiment will be described with reference to FIG. 1 to FIG. 4.

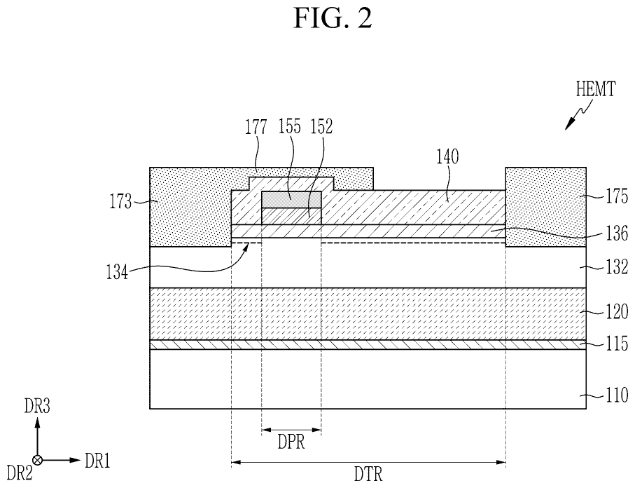

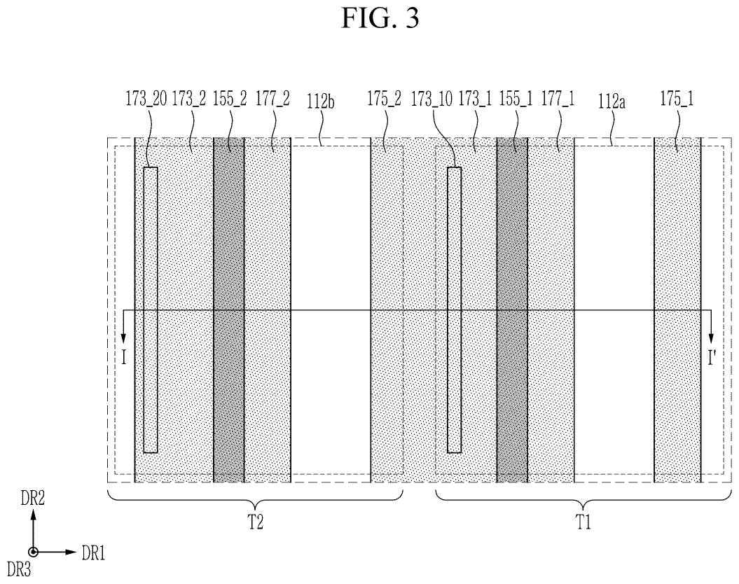

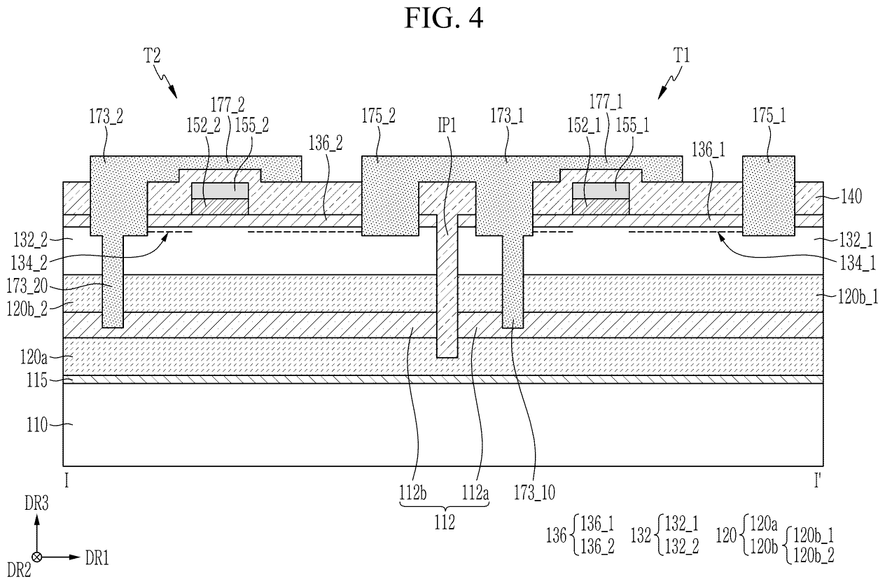

FIG. 1 illustrates a circuit diagram of a semiconductor device according to an embodiment. FIG. 2 illustrates a cross-sectional view showing a high electron mobility transistor (HEMT) of a semiconductor device according to an embodiment. FIG. 3 illustrates a top plan view showing an amplification circuit of a semiconductor device according to an embodiment. FIG. 3 shows a source electrode, a drain electrode, and a gate electrode of transistors constituting an amplification circuit according to an embodiment, and remaining components are omitted. FIG. 4 illustrates a cross-sectional view taken along line I-I′ according to an embodiment.

Referring to FIG. 1, a semiconductor device 10 is a power semiconductor device that converts, controls, or distributes supplied power, and may include a high electron mobility transistor HEMT and an amplification circuit AMP connected thereto. The power semiconductor device 10 may operate at high power. The amplification circuit AMP may amplify a control signal received from an external source (e.g., an integrated circuit included outside or inside a semiconductor device). The control signal may have a small power that is not sufficient to drive the power semiconductor device. The amplification circuit AMP may generate a gate signal by amplifying the control signal, and may supply the gate signal to the high electron mobility transistor HEMT. The high electron mobility transistor HEMT may be an individual component constituting a power semiconductor device (e.g., an inverter, a converter, a power management IC (PMIC), and/or a power distribution unit (PDU)) that performs a function of converting, controlling, or distributing supplied power.

The high electron mobility transistor HEMT may perform a switching operation based on the gate signal received from the amplification circuit AMP. The gate signal may be an electrical signal provided to a terminal of the high electron mobility transistor HEMT. For example, the gate signal may be a voltage (or current) provided to the gate electrode of the high electron mobility transistor HEMT. The high electron mobility transistor HEMT may perform on/off operations depending on the gate signal applied to the gate electrode of the high electron mobility transistor HEMT. The semiconductor device may convert, control, or distribute supplied power by controlling the on/off operation of the high electron mobility transistor H HEMT

In FIG. 1, one high electron mobility transistor HEMT is shown connected to the amplification circuit AMP, but the present invention is not limited thereto. A plurality of high electron mobility transistors may be connected to the amplification circuit AMP. For example, a plurality of high electron mobility transistors may be connected in parallel with each other. Additionally, in addition to the transistor, other individual elements that perform switching operations, such as diodes and thyristors, may be connected to the amplification circuit AMP.

The amplification circuit AMP may include a first transistor T1 and a second transistor T2 connected in series with each other, and a capacitor C connected in parallel to the first transistor T1 and the second transistor T2. A drain electrode of the first transistor T1 and a first electrode of the capacitor C may be connected to a first power voltage VDD. The first power voltage VDD may be connected to a power source. The first power voltage VDD may be supplied from the power source. A source electrode of the second transistor T2 and a second electrode of the capacitor C may be connected to a second power voltage VSS. The second power voltage VSS may have a voltage level lower than that of the first power voltage VDD. For example, the second power voltage VSS may be connected to a ground. However, the present invention is not limited thereto, and the second power voltage VSS may have a negative voltage level or a positive voltage level that is lower than that of the first power voltage VDD. A source electrode of the first transistor T1 and a drain electrode of the second transistor T2 may be connected to an output node N.

The first transistor T1 may be connected to a relatively higher voltage than the second transistor T2, and the second transistor T2 may be connected to a relatively lower voltage than the first transistor T1, so hereafter, the first transistor T1 may be referred to as a high side transistor, and the second transistor T2 may be referred to as a low side transistor.

A drain electrode of the high electron mobility transistor HEMT may be connected to a third power voltage VD, and a source electrode of the high electron mobility transistor HEMT may be connected to other components included in an electric vehicle, an electric tram, a solar power generator, a wind power generator, a mobile device, a converter, a PMIC, a PDU, etc. However, the present invention is not limited thereto, for example, the source electrode of the high electron mobility transistor HEMT may be connected to the second power voltage VSS. The third power voltage VD may have a higher level than the first power voltage VDD and the second power voltage VSS. A gate electrode of the high electron mobility transistor HEMT may be connected to an output node N of the amplification circuit AMP.

For example, the first transistor T1 may be a pull-up transistor, and the second transistor T2 may be a pull-down transistor. A pull-up signal GU may be applied to the gate electrode of the first transistor T1, and a pull-down signal GD may be applied to the gate electrode of the second transistor T2. The pull-up signal GU and the pull-down signal GD may be complementary. If the pull-up signal GU is at a first level, the pull-down signal GD may have a second level that is lower than the first level. When the pull-up signal GU is at the second level, the pull-down signal GD may have the first level that is higher than the second level. The first level may be a voltage that turns on the first transistor T1 or the second transistor T2, and the second level may be a voltage that turns off the first transistor T1 or the second transistor T2.

When the pull-up signal GU of the first level is applied to the first transistor T1 and the pull-down signal GD of the second level is applied to the second transistor T2, the first power voltage VDD may be applied to the gate electrode of the high electron mobility transistor H HEMT. The first power voltage VDD has a voltage level that is higher than a threshold voltage of the high electron mobility transistor HEMT, so the high electron mobility transistor HEMT may be turned on.

When the pull-up signal GU of the second level is applied to the first transistor T1 and the pull-down signal GD of the first level is applied to the second transistor T2, the gate electrode of the high electron mobility transistor HEMT may be connected to the second power voltage VSS. That is, charges charged at the gate electrode of the high electron mobility transistor HEMT may escape to the second power voltage VSS through the second transistor T2, and the high electron mobility transistor HEMT may be turned off.

The capacitor C may be a decoupling capacitor. For example, when the high electron mobility transistor HEMT turns off, a voltage of the gate electrode of the high electron mobility transistor HEMT may rapidly drop to the same level as that of the second power voltage VSS. The capacitor C may ensure that a voltage of the drain electrode of the first transistor T1 is maintained at the same level as the first power supply voltage VDD without being affected by a voltage of the gate electrode of the high electron mobility transistor HEMT. For example, when the high electron mobility transistor HEMT is turned on, a voltage stored in the capacitor C may be supplied as a voltage of the drain electrode of the first transistor T1. In this case, a uniform voltage (e.g., a voltage corresponding to a potential difference between the first power voltage VDD and the second power voltage VSS) may be supplied as the voltage of the drain electrode of the first transistor T1 regardless of a position of the high-electron mobility transistor HEMT.

In FIG. 1, one high electron mobility transistor HEMT is shown connected to the amplification circuit AMP, but the present invention is not limited thereto. A plurality of high electron mobility transistors may be connected to the amplification circuit AMP. The high electron mobility transistors may be connected in parallel with each other. A drain electrode of each of the high electron mobility transistors may be commonly connected to the third power voltage VD, and a source electrode of each of the high electron mobility transistors may be commonly connected to the second power voltage VSS. Gate signals having the same level may be respectively supplied to gate electrodes of the high electron mobility transistors at the same time, and accordingly, reliability of a switching operation performed by a single unit block formed of the high electron mobility transistors may be improved.

Referring to FIG. 2, the high electron mobility transistor HEMT may include a channel layer 132, a barrier layer 136 positioned on the channel layer 132, a gate electrode 155 positioned on the barrier layer 136, a source electrode 173 positioned at an opposite side of the gate electrode 155 on the channel layer 132, and a drain electrode 175.

The channel layer 132 is a layer that forms a channel between the source electrode 173 and the drain electrode 175, and a two-dimensional electron gas (2DEG) 134 may be positioned inside the channel layer 132. The two-dimensional electron gas 134 is a charge transport model used in solid physics, and refers to a group of electrons that can move freely in two dimensions (e.g., the x-y plane direction) but cannot move in another dimension (e.g., the z direction) and are tightly bound within the two dimensions. For example, the two-dimensional electron gas 134 may exist in a two-dimensional paper-like form within a three-dimensional space. This two-dimensional electron gas 134 may mainly appear in a semiconductor heterojunction structure, and in a high electron mobility transistor HEMT according to an embodiment, it may occur at an interface between the channel layer 132 and the barrier layer 136. For example, the two-dimensional electron gas 134 may be generated in a portion adjacent to the barrier layer 136 within the channel layer 132. The channel layer 132 may include one or more materials selected from Group III-V materials, e.g., nitrides containing Al, Ga, In, B, or a combination thereof. The channel layer 132 may be formed as a single layer or multiple layers. The channel layer 132 may be AlₓIn_{y}Ga_{1-x-y}N(0≤x≤1, 0≤y≤1, and x+y≤1). For example, the channel layer 132 may include or be formed of AlN, GaN, InN, InGaN, AlGaN, AlInN, AlInGaN, or a combination thereof. The channel layer 132 may be a layer doped with impurities or a layer undoped with impurities. A thickness of the channel layer 132 may be about several hundred nm or less.

The channel layer 132 may be disposed on a substrate 110. The substrate 110 may include a semiconductor material. For example, the substrate 110 may include Si. For example, the substrate 110 may be a p-type Si substrate doped with p-type impurities, but the present invention is not limited thereto. According to another embodiment, the substrate 110 may be an n-type Si substrate doped with n-type impurities.

A seed layer 115 and a buffer layer 120 may be disposed between the substrate 110 and the channel layer 132. The substrate 110, the seed layer 115, and the buffer layer 120 are layers necessary to form the channel layer 132, and may be omitted in some cases. For example, when a substrate made of GaN is used as the channel layer 132, at least one of the substrate 110, the seed layer 115, or the buffer layer 120 may be omitted. Considering that a price of a substrate made of GaN is relatively high, the channel layer 132 including GaN may be grown using the substrate 110 made of Si. In this case, as a lattice structure of Si and a lattice structure of GaN are different, it may not be easy to grow the channel layer 132 directly on the substrate 110. Accordingly, the seed layer 115 and the buffer layer 120 may first be grown on the substrate 110, and then the channel layer 132 may be grown on the buffer layer 120. Additionally, at least one of the substrate 110, the seed layer 115, and the buffer layer 120 may be removed from a final structure of the high electron mobility transistor HEMT after being used in the manufacturing process.

The seed layer 115 may be disposed directly on the substrate 110. However, the present invention is not limited thereto, and another predetermined layer may be further disposed between the substrate 110 and the seed layer 115. The seed layer 115 is a layer that serves as a seed for growing the buffer layer 120, and may be made of a crystal lattice structure that serves as a seed for the buffer layer 120. The buffer layer 120 may be disposed directly on the seed layer 115. However, the present invention is not limited thereto, and another predetermined layer may be further disposed between the seed layer 115 and the buffer layer 120. The seed layer 115 may include one or more materials selected from Group III-V materials, e.g., nitrides containing Al, Ga, In, B, or a combination thereof. The seed layer 115 may be AlxInyGa1-x-yN(0≤x≤1, 0≤y≤1, x+y≤1). For example, the seed layer 115 may include or be formed of AlN, GaN, InN, InGaN, AlGaN, AlInN, AlInGaN, or a combination thereof.

The buffer layer 120 may be disposed on the seed layer 115. The buffer layer 120 may be disposed between the seed layer 115 and the channel layer 132. The buffer layer 120 may be a layer to alleviate a difference in lattice constant and thermal expansion coefficient between the seed layer 115 and the channel layer 132, or to prevent leakage current from flowing through the channel layer 132. The buffer layer 120 may include one or more materials selected from Group III-V materials, e.g., nitrides containing Al, Ga, In, B, or a combination thereof. The buffer layer 120 may be AlₓIn_{y}Ga_{l-x-y}N(0≤x≤1, 0≤y≤1, x+y≤1). For example, buffer layer 120 may include AlN, GaN, InN, InGaN, AlGaN, AlInN, AlInGaN, or a combination thereof.

The buffer layer 120 of the high electron mobility transistor HEMT may include a superlattice layer disposed on the seed layer 115 and a high-resistance layer disposed on the superlattice layer. The superlattice layer and the high-resistivity layer may be sequentially disposed on the substrate 110.

The superlattice layer may be disposed on the seed layer 115. The superlattice layer may be disposed directly on the seed layer 115. However, the present invention is not limited thereto, and another predetermined layer may be further disposed between the seed layer 115 and the superlattice layer. The superlattice layer is a layer to alleviate the difference in lattice constant and coefficient of thermal expansion between the substrate 110 and the channel layer 132, to alleviate tensile stress and compressive stress thus-generated between the substrate 110 and the channel layer 132, and to alleviate the stress between the entire layers formed by growth in a final structure of the high electron mobility transistor HEMT according to an embodiment. The superlattice layer may include one or more materials selected from Group III-V materials, e.g., nitrides containing Al, Ga, In, B, or a combination thereof. The superlattice layer may be AlₓIn_{y}Ga_{l-x-y}N (0≤x≤1, 0≤y≤1, x+y≤1). For example, the superlattice layer may include AlN, GaN, InN, InGaN, AlGaN, AlInN, AlInGaN, or a combination thereof.

In an embodiment, the superlattice layer may be formed of multiple layers of alternating layers containing different materials. For example, the superlattice layer may have a structure in which a layer made of AlGaN and a layer made of AlN are repeatedly stacked. For example, AlGaN/AlN/AlGaN/AlN/AlGaN/AlN may be sequentially stacked to form the superlattice layer. A number of AlGaN layers and GaN that make up the superlattice layer may be varied, and a material that makes up the superlattice layer may be varied. As another example, the superlattice layer may have a structure in which a layer made of AlGaN and a layer made of GaN are repeatedly stacked. For example, AlGaN/GaN/AlGaN/GaN/AlGaN/GaN may be sequentially stacked to form the superlattice layer. In an embodiment, when the superlattice layer includes GaN, InN, AlGaN, AlInN, InGaN, AlN, AlInGaN, or a combination thereof, the superlattice layer may have n-type semiconductor characteristics in which the concentration of electrons is greater than the concentration of holes, but the present invention is not limited thereto.

The high-resistance layer may be disposed on the superlattice layer. The high-resistance layer may be disposed directly on the superlattice layer. However, the present invention is not limited thereto, and another predetermined layer may be further disposed between the superlattice layer and the high-resistance layer. The high-resistance layer may be disposed between the superlattice layer and the channel layer 132. The high-resistance layer is a layer to prevent the high electron mobility transistor HEMT according to an embodiment from being deteriorated by preventing leakage current from flowing through the channel layer 132. The high-resistance layer may be made of a low-conductivity material to electrically insulate the substrate 110 and the channel layer 132. The high-resistance layer may include one or more materials selected from Group III-V materials, e.g., nitrides containing Al, Ga, In, B, or a combination thereof. The high-resistance layer may be AlₓIn_{y}Ga_{l-x-y}N(0≤x≤1, 0≤y≤1, x+y≤1). For example, the high-resistance layer may include AlN, GaN, InN, InGaN, AlGaN, AlInN, AlInGaN, or a combination thereof. The high-resistance layer may be formed as a single layer or a multilayer.

The barrier layer 136 may be disposed on the channel layer 132. The barrier layer 136 may be disposed directly on the channel layer 132. However, the present invention is not limited thereto, and another predetermined layer may be further disposed between the channel layer 132 and the barrier layer 136. A region of the channel layer 132 that overlaps the barrier layer 136 between the source electrode 173 and the drain electrode 175 may be a drift region DTR. The drift region DTR may be positioned between the source electrode 173 and the drain electrode 175. The drift region DTR may refer to a region to which carriers move when a potential difference occurs between the source electrode 173 and the drain electrode 175.

The high electron mobility transistor HEMT according to one embodiment may be turned on/off depending on whether a voltage is applied to the gate electrode 155 and/or magnitude of the voltage applied to the gate electrode 155, and accordingly movement of carriers may be achieved or blocked in the drift region DTR.

The barrier layer 136 may include one or more materials selected from Group III-V materials, e.g., nitrides containing Al, Ga, In, B, or a combination thereof. The barrier layer 136 may be AlₓIn_{y}Ga_{l-x-y}N(0≤x≤1, 0≤y≤1, x+y≤1). The barrier layer 136 may include or be formed of GaN, InN, AlGaN, AlInN, InGaN, AlN, AlInGaN or a combination thereof. In an embodiment, an energy band gap of the barrier layer 136 may be adjusted by a composition ratio of Al and/or In.

The barrier layer 136 may include a semiconductor material with characteristics that are different from those of the channel layer 132. The barrier layer 136 may be different from the channel layer 132 in at least one of a polarization characteristic, an energy band gap, and a lattice constant. For example, the barrier layer 136 may include a material having a different energy band gap than that of the channel layer 132. In this case, the barrier layer 136 may have a higher energy band gap than the channel layer 132, and may have a higher electrical polarization rate than the channel layer 132. The two-dimensional electron gas 134 may be induced in the channel layer 132 having a relatively low electrical polarization rate by the barrier layer 136. In this regard, the barrier layer 136 may also be called a channel supply layer or a two-dimensional electron gas supply layer. The two-dimensional electron gas 134 may be formed within a portion of the channel layer 132 positioned below an interface between the channel layer 132 and the barrier layer 136. The two-dimensional electron gas 134 may have very high electron mobility.

The barrier layer 136 may be formed as a single layer or multiple layers. When the barrier layer 136 is made of multiple layers, materials of each of the layers constituting the multiple layers may have different energy band gaps. In this case, the various layers constituting the barrier layer 136 may be arranged so that an energy band gap increases as the layers approach the channel layer 132.

The gate electrode 155 may be positioned on the barrier layer 136. The gate electrode 155 may overlap a region of the barrier layer 136. The gate electrode 155 may overlap a portion of the drift region DTR of the channel layer 132. The gate electrode 155 may be positioned between the source electrode 173 and the drain electrode 175. The gate electrode 155 may be spaced apart from the source electrode 173 and the drain electrode 175 in a first direction DR1. The first direction DR1 may be a direction parallel to an upper surface of the substrate 110 or an upper surface of the channel layer 132. Although not shown, the gate electrode 155 may be positioned approximately at a center between the source electrode 173 and the drain electrode 175. For example, a separation distance between the gate electrode 155 and the source electrode 173 in the first direction DR1 is similar to a separation distance between the gate electrode 155 and the drain electrode 175 in the first direction DR1. However, a position of the gate electrode 155 is not limited thereto, and may be changed in various ways. The gate electrode 155 may be positioned closer to the source electrode 173 than the drain electrode 175. For example, a separation distance between the gate electrode 155 and the source electrode 173 may be smaller than a separation distance between the gate electrode 155 and the drain electrode 175.

The gate electrode 155 may extend in a second direction DR2 that is different from the first direction DR1 in a plan view. The second direction DR2 may be a direction parallel to the upper surface of the substrate 110 or the upper surface of the channel layer 132, and may be a direction that intersects the first direction DR1. For example, the second direction DR2 may be perpendicular to the first direction DR1. The gate electrode 155 may have a bar shape extending along the second direction DR2.

The gate electrode 155 may include a conductive material. For example, the gate electrode 155 may include a metal, a metal alloy, a conductive metal nitride, a metal silicide, a doped semiconductor material, a conductive metal oxide, or a conductive metal nitride. For example, the gate electrode 155 may include a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride. (TiAlN), a tantalum aluminum nitride (TaAlN), a tungsten nitride (WN), ruthenium (Ru), titanium aluminum (TiAl), a titanium aluminum carbonizationnitride (TiAlC-N), a titanium aluminum carbide (TiAlC), a titanium carbide (TiC), a tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), a molybdenum nitride (MoN), molybdenum carbide (MoC), a tungsten carbide (WC), rhodium (Rh), palladium (Pd), iridium (Ir), osmium (Os), silver (Ag), gold (Au), zinc (Zn), vanadium (V), or a combination thereof. but is not limited thereto. The gate electrode 155 may be formed as a single layer or multiple layers.

In some embodiments, the semiconductor device may further include a hard mask layer disposed on the gate electrode 155. The hard mask layer may be a hard mask used when forming the gate electrode 155 and patterning a gate electrode material layer or a gate semiconductor layer. However, the hard mask layer may be removed depending on etching conditions when etching the gate electrode material layer or cleaning conditions after etching. For example, the hard mask layer may include a silicon oxide, a silicon nitride, a silicon oxynitride, a combination thereof.

The high electron mobility transistor HEMT according to an embodiment may further include a gate semiconductor layer 152 disposed between the barrier layer 136 and the gate electrode 155. The gate semiconductor layer 152 may be disposed on the barrier layer 136. The gate electrode 155 may be positioned on the gate semiconductor layer 152. The gate electrode 155 may in contact with the gate semiconductor layer 152. The term “contact” or “in contact with” as used herein refers to a direct connection, e.g., touching. A lower surface of the gate electrode 155 may be in contact with the gate semiconductor layer 152. However, the present invention is not limited thereto, and another predetermined layer may be further disposed between the gate electrode 155 and the gate semiconductor layer 152. The gate electrode 155 may be in Schottky contact with the gate semiconductor layer 152. However, the present invention is not limited thereto, and in some cases, the gate electrode 155 may be in ohmic contact with the gate semiconductor layer 152. The gate semiconductor layer 152 may overlap the gate electrode 155 in a third direction DR3. The third direction DR3 may be a direction perpendicular to the first direction DR1 and the second direction DR2. That is, the third direction DR3 may be a direction perpendicular to the upper surface of the substrate 110 or the upper surface of the channel layer 132. The gate electrode 155 may be patterned using the same mask as that of the gate semiconductor layer 152. Accordingly, the gate electrode 155 may have the same planar shape as the gate semiconductor layer 152. The gate electrode 155 may have the same width as the gate semiconductor layer 152.

The semiconductor layer 152 may be disposed between the source electrode 173 and the drain electrode 175. The gate semiconductor layer 152 may be spaced apart from the source electrode 173 and the drain electrode 175. The gate semiconductor layer 152 may be disposed approximately at a center between the source electrode 173 and the drain electrode 175. For example, a separation distance between the gate semiconductor layer 152 and the source electrode 173 in the first direction DRI is similar to a separation distance between the gate semiconductor layer 152 and the drain electrode 175 in the first direction DR1. However, a position of the gate semiconductor layer 152 is not limited thereto, and may be changed in various ways. The gate semiconductor layer 152 may be disposed closer to the source electrode 173 than the drain electrode 175. For example, a separation distance between the gate semiconductor layer 152 and the source electrode 173 may be smaller than a separation distance between the gate semiconductor layer 152 and the drain electrode 175.

The gate semiconductor layer 152 may include one or more materials selected from group III-V materials, e.g., nitrides including at least one of Al, Ga, In, or B. The gate semiconductor layer 152 may be AlₓIn_{y}Ga_{l-x-y}N(0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material having a different energy band gap from that of the barrier layer 136. For example, the gate semiconductor layer 152 may include GaN, and the barrier layer 136 may include AlGaN. The gate semiconductor layer 152 may be doped with a predetermined impurity. In this case, the impurity doped in the gate semiconductor layer 152 may be a P-type impurity that can provide a hole. For example, the gate semiconductor layer 152 may include GaN doped with p-type impurities. For example, the gate semiconductor layer 152 may be made of a p-GaN layer. The present invention is not limited thereto, and the gate semiconductor layer 152 may be a p-AlGaN layer. For example, the impurity doped in the gate semiconductor layer 152 may be magnesium (Mg). The gate semiconductor layer 152 may be formed as a single layer or multiple layers.

A depletion region DPR may be formed within the channel layer 132 by the gate semiconductor layer 152. The depletion region DPR may be positioned within the drift region DTR, and may have a narrower width than the drift region DTR. As the gate semiconductor layer 152 having a different energy band gap from that of the barrier layer 136 is disposed on the barrier layer 136, a level of an energy band of a portion of the barrier layer 136 that overlaps the gate semiconductor layer 152 may increase. Accordingly, the depletion region DPR may be formed in a region of the channel layer 132 that overlaps the gate semiconductor layer 152. The depletion region DPR may be a region in a channel path of the channel layer 132 where the two-dimensional electron gas 134 is not formed, or may have a lower electron concentration than remaining regions. For example, the depletion region DPR may indicate a region where a flow of the two-dimensional electron gas 134 is interrupted within the drift region DTR. As the depletion region DPR occurs, a current does not flow between the source electrode 173 and the drain electrode 175, and the channel path may be blocked. Accordingly, the high electron mobility transistor HEMT according to an embodiment may have a normally off characteristic.

For example, the high electron mobility transistor HEMT according to an embodiment may be a normally off high electron mobility transistor (HEMT). In a normal state in which no voltage is applied to the gate electrode 155, the depletion region DPR may exist, and the high electron mobility transistor HEMT according to an embodiment may be in an off state. When a voltage greater than a threshold voltage of the high electron mobility transistor HEMT is applied to the gate electrode 155, the depletion region DPR may disappear, and the two-dimensional electron gas 134 may be connected without being disconnected within the drift region DTR. For example, two-dimensional electron gas 134 may be formed throughout a channel path between the source electrode 173 and the drain electrode 175, and the high electron mobility transistor HEMT according to an embodiment may be in an on state. In summary, the high electron mobility transistor HEMT according to an embodiment may include semiconductor layers with different electrical polarization characteristics, and a semiconductor layer with a relatively large polarization may induce the two-dimensional electron gas 134 in another semiconductor layer that is heterogeneously bonded therewith. This two-dimensional electron gas 134 may be used as a channel between the source electrode 173 and the drain electrode 175, and continuation or interruption of a flow of this two-dimensional electron gas 134 may be controlled by a bias voltage applied to the gate electrode 155. In a gate off state, the flow of the two-dimensional electron gas 134 may be blocked, so a current may not flow between the source electrode 173 and the drain electrode 175. As the two-dimensional electron gas 134 continues to flow in a gate on state, a current may flow between the source electrode 173 and the drain electrode 175.

Although a case where the high electron mobility transistor HEMT according to an embodiment is a normally off high electron mobility transistor HEMT has been described above, the present invention is not limited thereto. For example, the high electron mobility transistor HEMT according to an embodiment may be a normally on high electron mobility transistor, in which case the gate semiconductor layer 152 may be omitted. Accordingly, the gate electrode 155 may be positioned directly on the barrier layer 136. In this structure, the two-dimensional electron gas 134 may be used as a channel while no voltage is applied to the gate electrode 155, and a current flow may occur between the source electrode 173 and the drain electrode 175. Additionally, when a negative voltage is applied to the gate electrode 155, the depletion region DPR in which the flow of two-dimensional electron gas 134 is interrupted may occur at a lower portion of the gate electrode 155.

The seed layer 115, the buffer layer 120, the channel layer 132, the barrier layer 136, and the gate semiconductor layer 152 described above may be sequentially stacked on the substrate 110. In the high electron mobility transistor HEMT according to one embodiment, at least one of the seed layer 115, the buffer layer 120, the channel layer 132, the barrier layer 136, and the gate semiconductor layer 152 may be omitted. These seed layer 115, buffer layer 120, channel layer 132, barrier layer 136, and gate semiconductor layer 152 may be made of the same base semiconductor material as each other, and a material composition ratio of each layer may be different considering a role of each layer, performance required for the high electron mobility transistor HEMT, etc.

The high electron mobility transistor HEMT according to an embodiment may further include a first protective layer 140 positioned on portions of the barrier layer 136, the gate semiconductor layer 152, and the gate electrode 155. The first protective layer 140 may cover an upper surface of the portion of the barrier layer 136, a side surface of the gate semiconductor layer 152, and an upper surface and a side surface of the gate electrode 155. The first protective layer 140 may be in contact with the barrier layer 136, the gate semiconductor layer 152, and the gate electrode 155. The barrier layer 136, the gate semiconductor layer 152, and the gate electrode 155 may be protected by the first protective layer 140, and may be separated from other components. The first protective layer 140 may include an insulating material. For example, the first protective layer 140 may include an oxide such as SiO₂ or Al₂O₃. As another example, the first protective layer 140 may include a nitride such as SiN or an acid nitride such as SiON. The first protective layer 140 may be formed as a single layer or multiple layers.

The source electrode 173 and the drain electrode 175 are positioned on the channel layer 132. The source electrode 173 and the drain electrode 175 may be spaced apart from each other, and the gate electrode 155 and the gate semiconductor layer 152 may be disposed between the source electrode 173 and the drain electrode 175. The gate electrode 155 and the gate semiconductor layer 152 are spaced apart from the source electrode 173 and the drain electrode 175. The source electrode 173 may be electrically connected to the channel layer 132 at a first side of the gate electrode 155. The drain electrode 175 may be electrically connected to the channel layer 132 at a second side of the gate electrode 155. The source electrode 173 and drain electrode 175 may be positioned outside the drift region DTR of the channel layer 132. A boundary between the source electrode 173 and the channel layer 132 may be a first edge of the drift region DTR. As such, a boundary between the drain electrode 175 and the channel layer 132 may be a second edge of the drift region DTR. However, the present invention is not limited thereto, and the source electrode 173 and the drain electrode 175 may not be positioned outside the drift region DTR of the channel layer 132. In this case, the channel layer 132 may not be recessed, and the source electrode 173 and the drain electrode 175 may be positioned on an upper surface of the channel layer 132. Alternatively, the barrier layer 136 may not be penetrated, and a portion of the barrier layer 136 may be recessed, so that the source electrode 173 and the drain electrode 175 may be positioned on the upper surface of the barrier layer 136. Lower surfaces of the source electrode 173 and the drain electrode 175 may be in contact with an upper surface of the barrier layer 136. A portion of the barrier layer 136 in contact with the source electrode 173 and the drain electrode 175 may be doped at a high concentration. In this case, carriers passing through the two-dimensional electron gas 134 may be transferred to the source electrode 173 and the drain electrode 175 through a portion of the barrier layer 136 that is heavily doped, i.e., an upper portion of the two-dimensional electron gas 134. The source electrode 173 and the drain electrode 175 may not directly contact the two-dimensional electron gas 134 in a horizontal direction. The horizontal direction may refer to a direction parallel to an upper surface of the channel layer 132 or the barrier layer 136.

The source electrode 173 and the drain electrode 175 are positioned on the first protective layer 140. Trenches that extend through the first protective layer 140 and the barrier layer 136 and recesses the upper surface of the channel layer 132 may be respectively positioned at opposite sides of the gate electrode 155 to be spaced apart from each other. The source electrode 173 and the drain electrode 175 may be positioned in the trenches positioned at opposite sides of the gate electrode 155, respectively. The source electrode 173 and the drain electrode 175 can be formed to fill insides of the trenches. Within the trenches, the source electrode 173 and the drain electrode 175 may be in contact with the channel layer 132 and the barrier layer 136. The channel layer 132 may form a bottom surface and sidewalls of the trench, and the barrier layer 136 may form sidewalls of the trench. Accordingly, the source electrode 173 and the drain electrode 175 may contact upper and side surfaces of the channel layer 132. In addition, the source electrode 173 and the drain electrode 175 may be in contact with a side surface of the barrier layer 136. That is, the source electrode 173 and the drain electrode 175 may cover side surfaces of the channel layer 132 and the barrier layer 136. Upper surfaces of the source electrode 173 and the drain electrode 175 may protrude beyond an upper surface of the first protective layer 140. In some cases, at least one of the source electrode 173 or the drain electrode 175 may cover at least a portion of the upper surface of the first protective layer 140.

The source electrode 173 and the drain electrode 175 may be spaced apart in the first direction DR1. The source electrode 173 and the drain electrode 175 may extend in the second direction DR2 in a plan view. The source electrode 173 and the drain electrode 175 may extend in a direction parallel to the gate electrode 155.

Each of the source electrode 173 and the drain electrode 175 may include a conductive material. For example, each of the source electrode 173 and the drain electrode 175 may include a metal, a metal alloy, a conductive metal nitride, a metal silicide, a doped semiconductor material, a conductive metal oxide, or a conductive metal nitride. For example, each of the source electrode 173 and the drain electrode 175 may include a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride. (TiAlN), a tantalum aluminum nitride (TaAlN), a tungsten nitride (WN), ruthenium (Ru), titanium aluminum (TiAl), a titanium aluminum carbonizationnitride (TiAlC-N), a titanium aluminum carbide (TiAlC), a titanium carbide (TiC), a tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), a molybdenum nitride (MoN), molybdenum carbide (MoC), a tungsten carbide (WC), rhodium (Rh), palladium (Pd), iridium (Ir), osmium (Os), silver (Ag), gold (Au), zinc (Zn), vanadium (V), or a combination thereof, but the present invention is not limited thereto. Each of the source electrode 173 and the drain electrode 175 may be formed as a single layer or a multilayer. Each of the source electrode 173 and the drain electrode 175 may be in ohmic contact with the channel layer 132. A region in contact with the source electrode 173 and the drain electrode 175 within the channel layer 132 may be doped at a relatively high concentration compared to other regions.

A field distribution layer 177 may be disposed between the source electrode 173 and the drain electrode 175. The field distribution layer 177 may overlap the gate electrode 155 in the third direction DR3. The gate electrode 155 may be covered by the field distribution layer 177. The field distribution layer 177 may be electrically connected to the source electrode 173. The field distribution layer 177 may include the same material as the source electrode 173, and may be disposed in the same layer as that of the source electrode 173. The field distribution layer 177 may be formed together in the same process as that of the source electrode 173. A boundary between the field distribution layer 177 and the source electrode 173 may not be clear, and the field distribution layer 177 may be formed integrally with the source electrode 173. However, the present invention is not limited thereto, and the field distribution layer 177 may be a separate component from the source electrode 173. Additionally, the field distribution layer 177 may be positioned in a different layer from that of the source electrode 173, and may be formed in a different process. In some cases, the field distribution layer 177 may be electrically connected to the gate electrode 155. For example, an opening overlapping the gate electrode 155 may be formed in the first protective layer 140, and the field distribution layer 177 may be connected to the gate electrode 155 through the opening. In this case, the field distribution layer 177 may not be connected to the source electrode 173.

The field distribution layer 177 may serve to distribute an electric field concentrated around the gate electrode 155. When a high voltage is applied to the drain electrode 175 in the gate off state, an electric field may be concentrated around the gate electrode 155. When the electric field is concentrated on the gate electrode 155, leakage current may increase and breakdown voltage may decrease. The electric field concentrated around the gate electrode 155 may be distributed by the field distribution layer 177, thereby reducing leakage current and increasing breakdown voltage.

In FIG. 2, the high electron mobility transistor HEMT according to an embodiment is shown as including a pair of source electrodes 173 and drain electrodes 175, but a number of source electrodes 173 and drain electrodes 175 is not limited thereto. For example, the source electrode 173 may include a plurality of source electrodes sequentially stacked in the third direction DR3 on the channel layer 132, and the drain electrode 175 may include a plurality of drain electrodes sequentially stacked in the third direction DR3 on the channel layer 132.

In FIG. 2, the high electron mobility transistor HEMT according to an embodiment is shown as including one field dispersion layer 177, but the present invention is not limited thereto. For example, the field distribution layer 177 may include a plurality of field distribution layers that overlap the gate electrode 155 in the third direction DR3. The field distribution layers may be spaced apart from each other in the third direction DR3 by a protective layer containing an insulating material. Each of the field dispersion layers may be disposed between a plurality of pairs of source electrodes 173 and drain electrodes 175. Each of the field dispersion layers may be electrically connected to a plurality of source electrodes. Each of the field distribution layers may be formed integrally with each of the source electrodes, but the present invention is not necessarily limited thereto. Among the field distribution layers, a first field distribution layer may entirely cover a second field distribution layer distributed between the first field distribution layer and the gate electrode 155. A width of the first field distribution layer may be larger than a width of the second field distribution layer. The width of the first field distribution layer and the width of the second field distribution layer may indicate a length along the first direction DR1 extending from the source electrode 173 to the drain electrode 175.

Referring to FIGS. 3 and 4, the first transistor T1 may include a first channel layer 132_1, a first barrier layer 136_1 disposed on the first channel layer 132_1, a first gate electrode 155_1 positioned on the first barrier layer 136_1, and a first source electrode 173_1 and a first drain electrode 175_1 positioned at opposite sides of the first gate electrode 155_1 on the first channel layer 132_1. The first transistor T1 may further include a first gate semiconductor layer 152_1 disposed between the first barrier layer 136_1 and the first gate electrode 155_1. A first field distribution layer 177_1 may be disposed between the first source electrode 173_1 and the first drain electrode 175_1.

The second transistor T2 may include a second channel layer 132_2, a second barrier layer 136_2 disposed on the second channel layer 132_2, a second gate electrode 155_2 positioned on the second barrier layer 136_2, and a second source electrode 173_2 and a second drain electrode 175_2 positioned at opposite sides of the second gate electrode 155_2 on the second channel layer 132_2. The second transistor T2 may further include a second gate semiconductor layer 152_2 disposed between the second barrier layer 136_2 and the second gate electrode 155_2. The second field distribution layer 177_2 may be disposed between the second source electrode 173_2 and the second drain electrode 175_2.

Each of the first transistor T1 and second transistor T2 may be a high electron mobility transistor. Components of the first transistor T1 and the components of the second transistor T2 may each correspond to components of the high electron mobility transistor HEMT described above with reference to FIG. 2. Each component of the first transistor T1 and the second transistor T2 may be formed together in the same process as that of the high electron mobility transistor HEMT.

The first channel layer 132_1 and the second channel layer 132_2 may correspond to the channel layer 132. For example, the first channel layer 132_1 and the second channel layer 132_2 may be formed together in the same process as that of the channel layer 132, and may include the same material. The first barrier layer 136_1 and the second barrier layer 136_2 may correspond to the barrier layer 136. For example, the first barrier layer 136_1 and the second barrier layer 136_2 may be formed together in the same process as that of the barrier layer 136, and may include the same material. The first gate electrode 155_1 and the second gate electrode 155_2 may correspond to the gate electrode 155. For example, the first gate electrode 155_1 and the second gate electrode 155_2 may be formed together in the same process as that of the gate electrode 155, and may include the same material. The first gate semiconductor layer 152_1 and the second gate semiconductor layer 152_2 may correspond to the gate semiconductor layer 152. For example, the first gate semiconductor layer 152_1 and the second gate semiconductor layer 152_2 may be formed together in the same process as that of the gate semiconductor layer 152, and may include the same material.

The first source electrode 173_1 and the second source electrode 173_2 may correspond to the source electrode 173. The first drain electrode 175_1 and the second drain electrode 175_2 may correspond to the drain electrode 175. The first field distribution layer 177_1 and the second field distribution layer 177_2 may correspond to the field distribution layer 177. The first source electrode 173_1 and the first drain electrode 175_1 may be formed together in the same process as those of the second source electrode 173_2 and the second drain electrode 175_2, and may include the same material. The first source electrode 173_1 and the first drain electrode 175_1 may be formed together in the same process as those of the source electrode 173 and the drain electrode 175, and may include the same material. The second source electrode 173_2 and the second drain electrode 175_2 may be formed together in the same process as those of the source electrode 173 and the drain electrode 175, and may include the same material.

The first channel layer 132_1 may include a first drift region DTR1 that overlaps the first barrier layer 136_1 between the first source electrode 173_1 and the first drain electrode 175_1. The first drift region DTR1 may include a first depletion region DPR1 that overlaps the first gate semiconductor layer 152_1. A two-dimensional electron gas 134_1 may be positioned inside the first channel layer 132_1. When the first transistor T1 is in the on state, the two-dimensional electron gas 134_1 may continue to flow within the first drift region DTR1, thereby causing a current to flow between the first source electrode 173_1 and the first drain electrode 175_1. When the first transistor T1 is in the off state, a flow of the two-dimensional electron gas 134_1 may be cut off within the first depletion region DPR1, so that no current may flow between the first source electrode 173_1 and the first drain electrode 175_1.

The second channel layer 132_2 may include a second drift region DTR2 that overlaps the second barrier layer 136_2 between the second source electrode 173_2 and the second drain electrode 175_2. The second drift region DTR2 may include a second depletion region DPR2 that overlaps the second gate semiconductor layer 152_2. A two-dimensional electron gas 134_2 may be positioned inside the second channel layer 132_2. When the second transistor T2 is in the on state, the two-dimensional electron gas 134_2 of the second channel may continue to flow within the second drift region DTR2, thereby causing a current to flow between the second source electrode 173_2 and the second drain electrode 175_2. When the second transistor T2 is in the off state, a flow of the two-dimensional electron gas 134_2 of the second channel may be cut off within the second depletion region DPR2, so that no current may flow between the second source electrode 173_2 and the second drain electrode 175_2.

The first drift region DTR1 and the second drift region DTR2 may correspond to the drift region DTR, and the first depletion region DPR1 and the second depletion region DPR2 may correspond to the depletion region DPR. The two-dimensional electron gas 134_1 and the two-dimensional electron gas 134_2 may correspond to the two-dimensional electron gas 134.

A description of the components of the first transistor T1 and the second transistor T2 may be applied mostly identically or similarly to the description of the components of the corresponding high electron mobility transistor HEMT, and hereinafter, duplicate descriptions will be omitted and differences will be mainly described. Components of the first transistor T1 and second transistor T2 and components of the corresponding high electron mobility transistor HEMT may be positioned on the same layer. For example, the components of the first transistor T1 and the second transistor T2 and the components of the corresponding high electron mobility transistor HEMT may be formed together in the same process, but the present invention is not necessarily limited thereto.

As described above with reference to FIG. 1, the first transistor T1 is connected to the first power voltage VDD, and the second transistor T2 is connected to the second power voltage VSS, which is different from the first power voltage VDD. The second power voltage VSS may be lower than the first power voltage VDD, and may be connected to a ground. Additionally, first transistor T1 and second transistor T2 are connected in series with each other. Specifically, the first drain electrode 175_1 of the first transistor T1 is connected to the first power voltage, and the second source electrode 173_2 of the second transistor T2 is connected to the second power voltage. The first power voltage may be higher than the second power voltage. The first source electrode 173_1 of the first transistor T1 and the second drain electrode 175_2 of the second transistor T2 are connected to each other.

In FIGS. 3 and 4, the first source electrode 173_1 and the second drain electrode 175_2 are shown as being formed as a single unit, but the present invention is not necessarily limited thereto. The first source electrode 173_1 and the second drain electrode 175_2 may be separate components, in which case the first source electrode 173_1 and the second drain electrode 175_2 may be connected by another component.

The seed layer 115 and the buffer layer 120 may be disposed on the substrate 110. The substrate 110 may be a silicon substrate. For example, the substrate 110 may be a silicon substrate doped with p-type impurities.

The buffer layer 120 may be disposed on the seed layer 115. The buffer layer 120 may include a lower buffer layer 120a and an upper buffer layer 120b disposed on the lower buffer layer 120a. For example, the lower buffer layer 120a may include a stress relief layer and a high-resistance layer, and the upper buffer layer 120b may include a superlattice layer and a barrier layer including AlGaN, but the present invention is not limited thereto. The lower buffer layer 120a may further include a superlattice layer and a barrier layer including AlGaN, and the upper buffer layer 120b may further include a stress relief layer and a high-resistance layer. For example, when the lower buffer layer 120a and the upper buffer layer 120b each include a layer containing the same material, a corresponding layer included in the upper buffer layer 120b in contact with the channel layer 132 may have a better quality than a corresponding layer included in the lower buffer layer 120a that is separated from the channel layer 132. For example, the lower buffer layer 120a may include some defects.

The upper buffer layer 120b may include a first upper buffer layer 120b_1 and a second upper buffer layer 120b_2. The first upper buffer layer 120b_1 and the second upper buffer layer 120b_2 may be spaced apart in a direction parallel to the upper surface of the substrate 110 (e.g., first direction DR1).

According to an embodiment, a well region 112 may be positioned within the buffer layer 120. The well region 112 may include or be formed of the same semiconductor material as that of the channel layer 132. For example, the well region 112 may include or be formed of GaN. The well region 112 may be doped with n-type impurities. For example, the region 112 may include GaN doped with n-type impurities.

The well region 112 may include a first well region 112a positioned between the lower buffer layer 120a and the first upper buffer layer 120b_1, and a second well region 112b positioned between the lower buffer layer 120a and the second upper buffer layer 120b_2. According to an embodiment, the first transistor T1 may be positioned on the first well region 112a, and the second transistor T2 may be positioned on the second well region 112b. The first upper buffer layer 120b_1 may be positioned on the first well region 112a, and the first transistor T1 may be positioned on the first upper buffer layer 120b_1. The second upper buffer layer 120b_2 may be positioned on the second well region 112b, and the second transistor T2 may be positioned on the second upper buffer layer 120b_2.

The channel layer 132 may be disposed on the buffer layer 120. The channel layer 132 may include a first channel layer 132_1 disposed on the first upper buffer layer 120b_1 and a second channel layer 132_2 disposed on the second upper buffer layer 120b_2. The first channel layer 132_1 and the second channel layer 132_2 may be spaced apart in a direction parallel to the upper surface of the substrate 110 (e.g., first direction DR1). The first channel layer 132_1 may be disposed on the first well region 112a, and the second channel layer 132_2 may be disposed on the second well region 112b.

The barrier layer 136 may be disposed on the channel layer 132. The barrier layer 136 may include a first barrier layer 136_1 disposed on the first channel layer 132_1 and a second barrier layer 136_2 disposed on the second channel layer 132_2. The first barrier layer 136_1 and the second barrier layer 136_2 may be spaced apart in a direction parallel to the upper surface of the substrate 110 (e.g., first direction DR1).

The first gate electrode 155_1 may be positioned on the first barrier layer 136_1, and the second gate electrode 155_2 may be positioned on the second barrier layer 136_2. The first gate semiconductor layer 152_1 may be further disposed between the first gate electrode 155_1 and the first barrier layer 136_1, and the second gate semiconductor layer 152_2 may be further disposed between the second gate electrode 155_2 and the second barrier layer 136_2. The first source electrode 173_1 and the first drain electrode 175_1 may be positioned at opposite sides of the first gate electrode 155_1 on the first channel layer 132_1. The second source electrode 173_2 and the second drain electrode 175_2 may be positioned at opposite sides of the second gate electrode 155_2 on the second channel layer 132_2. The first source electrode 173 1 and first drain electrode 175_1 may be connected to the first channel layer 132_1, and the second source electrode 173_2 and second drain electrode 175_2 may be connected to the second channel layer 132_2.

The first source electrode 173_1 and the first drain electrode 175_1 may be spaced apart in the first direction DR1, and the first gate electrode 155_1 may be positioned between the first source electrode 173_1 and the first drain electrode 175_1. The first gate electrode 155_1 may be closer to the first source electrode 173_1 than the first drain electrode 175_1. The second source electrode 173_2 and the second drain electrode 175_2 may be spaced apart in the first direction DR1, and the second gate electrode 155_2 may be positioned between the second source electrode 173_2 and the second drain electrode 175_2. The second gate electrode 155_2 may be closer to the second source electrode 173_2 than the second drain electrode 175_2.

According to an embodiment, an insulating pattern IP1 may be positioned between the second drain electrode 175_2 and the first source electrode 173_1. The insulating pattern IP1 may be positioned between the first barrier layer 136_1 and the second barrier layer 136_2, between the first channel layer 132_1 and the second channel layer 132_2, and between the first upper buffer layer 120b_1 and the second upper buffer layer 120b_2, and between the first well region 112a and the second well region 112b. The first barrier layer 136_1 and the second barrier layer 136_2 may be spaced apart by the insulating pattern IP1. The first channel layer 132_1 and the second channel layer 132_2 may be spaced apart by the insulating pattern IP1. The first upper buffer layer 120b_1 and the second upper buffer layer 120b_2 may be spaced apart by the insulating pattern IP1. The first well region 112a and the second well region 112b may be spaced apart by the insulating pattern IP1. A point that any two components are separated by the insulating pattern IP1 may indicate that the two components are insulated with each other.

According to an embodiment, the insulating pattern IP1 may extend through the barrier layer 136, the channel layer 132, the upper buffer layer 120b, and the well region 112 in a direction perpendicular to an upper surface of the substrate 110. For example, a trench is formed that extends through the barrier layer 136, the channel layer 132, the upper buffer layer 120b, and the well region 112 in the direction perpendicular to the upper surface of the substrate 110, and the insulating pattern IP1 may be formed by filling the insulating material. By the trench, the barrier layer 136 may be divided into the first barrier layer 136_1 and the second barrier layer 136_2, the channel layer 132 may be divided into the first channel layer 132_1 and the second channel layer 132_2, the upper buffer layer 120b may be divided into the first upper buffer layer 120b_1 and the second upper buffer layer 120b_2, and the well region 112 may be divided into the first well region 112a and the second well region 112b.

In FIG. 4, the insulating pattern IP1 is shown as extending through the barrier layer 136, the channel layer 132, the upper buffer layer 120b, and the well region 112 and contacting the lower buffer layer 120a, but the present invention is limited thereto. For example, the insulating pattern IP1 may further extend through the lower buffer layer 120a to contact the seed layer 115. In some examples, the insulating pattern IP1 may further extend through the lower buffer layer 120a and the seed layer 115 to contact the substrate 110.

In FIG. 4, a width of the insulating pattern IP1 in the first direction DR1 is shown to be the same, but the present invention is not limited thereto, and the width of the insulating pattern IP1 in the first direction DR1 may become narrower as it approaches the upper surface of the substrate 110. For example, in FIG. 4, a cross-sectional shape of the insulating pattern IP1 in the first direction DR1 and the third direction DR3 is shown as a rectangle, but the present invention is not limited thereto, and the cross-sectional shape of the insulating pattern IP1 in the first direction DR1 and the third direction DR3 may have a trapezoidal shape whose width becomes narrower as it approaches the upper surface of the substrate 110.

The first protective layer 140 may cover upper and side surfaces of the first gate electrode 155_1 and the second gate electrode 155_2. The first protective layer 140 may cover sides of the first gate semiconductor layer 152_1 and the second gate semiconductor layer 152_2. The first protective layer 140 may cover portions of side surfaces of the first source electrode 173_1, the first drain electrode 175_1, the second source electrode 173_2, and the second drain electrode 175_2. Although not shown, the first protective layer 140 may further cover portions of upper surfaces of the first source electrode 173_1, the first drain electrode 175_1, the second source electrode 173_2, and the second drain electrode 175_2.

According to an embodiment, the insulating pattern IP1 may be formed integrally with the first protective layer 140. For example, the insulating pattern IP1 may be formed together with the first protective layer 140 in the same process. The insulating pattern IP1 may include or be formed of the same material as that of the first protective layer 140. For example, the insulating pattern IP1 may include or be formed of an oxide such as SiO₂ or Al₂O₃. In some examples, the insulating pattern IP1 may include or be formed of a nitride such as SiN or an acid nitride such as SiON. In some examples, the insulating pattern IP1 may include or be formed of Ar. The insulating pattern IP1 may be formed as a single layer or multiple layers. If each of the insulating pattern IP1 and the first protective layer 140 includes the same material, a boundary between the insulating pattern IP1 and the first protective layer 140 may not be visible. However, the present invention is not limited thereto, and the insulating pattern IP1 may be formed in a different process from that of the first protective layer 140, and may include a different material from that of the first protective layer 140.

According to an embodiment, the first source electrode 173_1 and the second drain electrode 175_2 may be connected to the well region 112. According to an embodiment, the first source electrode 173_1 and the second drain electrode 175_2 may be connected to the first well region 112a, and the second source electrode 173_2 may be connected to the second well region 112b.

The first source electrode 173_1 may include a first contact portion 173_10 that extends through the first channel layer 132_1 and the first upper buffer layer 120b_1 to contact the first well region 112a. A lower surface of the first contact portion 173_10 may be positioned between an upper surface of the lower buffer layer 120a and a lower surface of the first upper buffer layer 120b_1, but the present invention is not limited thereto. The lower surface of the first contact portion 173_10 may be positioned at the same level as the upper surface of the lower buffer layer 120a or the lower surface of the first upper buffer layer 120b_1.

The second source electrode 173_2 may include a second contact portion 173_20 that extends through the second channel layer 132_2 and the second upper buffer layer 120b_2 to contact the second well region 112b. A lower surface of the second contact portion 173_20 may be positioned between the upper surface of the lower buffer layer 120a and a lower surface of the second upper buffer layer 120b_2, but the present invention is not limited thereto. The lower surface of the second contact portion 173_20 may be positioned at the same level as the upper surface of the lower buffer layer 120a or the lower surface of the second upper buffer layer 120b_2.

In FIG. 3, the first contact portion 173_10 and the second contact portion 173_20 are shown as having a shape extending along the second direction DR2, but the present disclosure is not necessarily limited thereto. A width of the first contact portion 173_10 and the second contact portion 173_20 along the second direction DR2 may be changed in various ways. Additionally, in FIG. 3, the first contact portion 173_10 and the second contact portion 173_20 are shown as a single unit, but the present invention is not necessarily limited thereto. For example, a plurality of first contact portions and/or a plurality of second contact portions 173_20 may be arranged to be spaced apart at a predetermined interval along the second direction DR2.

Additionally, in FIG. 3, a planar shape of each of the first contact portion 173_10 and the second contact portion 173_20 is shown to be a quadrangle, but the present invention is not necessarily limited thereto. For example, the planar shape of each of the first contact portion 173_10 and the second contact portion 173_20 may be variously changed to a circle, an ellipse, or a polygon other than a quadrangle.

In FIG. 4, widths of the first contact portion 173_10 and the second contact portion 173_20 in the first direction DRI are shown to be the same, but the present invention is not limited thereto. The first contact portion 173_10 and the second contact portion 173_20 may have a shape having a width in the first direction DR1 that becomes narrower toward a lower surface thereof. For example, in FIG. 4, the cross-sectional shape of the first contact portion 173_10 and the second contact portion 173_20 along the first direction DR1 and the third direction DR3 is shown to be rectangular, but the present invention is not limited thereto. According to the above description, the cross-sectional shape of each of the first contact portion 173_10 and the second contact portion 173_20 along the first direction DR1 and the third direction DR3 may be trapezoidal.

According to an embodiment, the semiconductor device may include a first well region 112a and a second well region 112b positioned within the buffer layer 120 and spaced apart by the insulating pattern IP1, the first transistor T1 may be positioned on the first well region 112a, and the second transistor T2 may be positioned on the second well region 112b. The first source electrode 173_1 of the first transistor T1 and the second drain electrode 175_2 of the second transistor T2 may be connected to the first well region 112a, and the second source electrode 173_2 of the second transistor T2 may be connected to the second well region 112b. According to an embodiment, it may be possible to form two high electron mobility transistors connected in series on one substrate between a first power voltage and a second power voltage that is lower than the first power voltage by using a silicon substrate that is cheaper than a silicon-on-insulator (SOI) substrate.

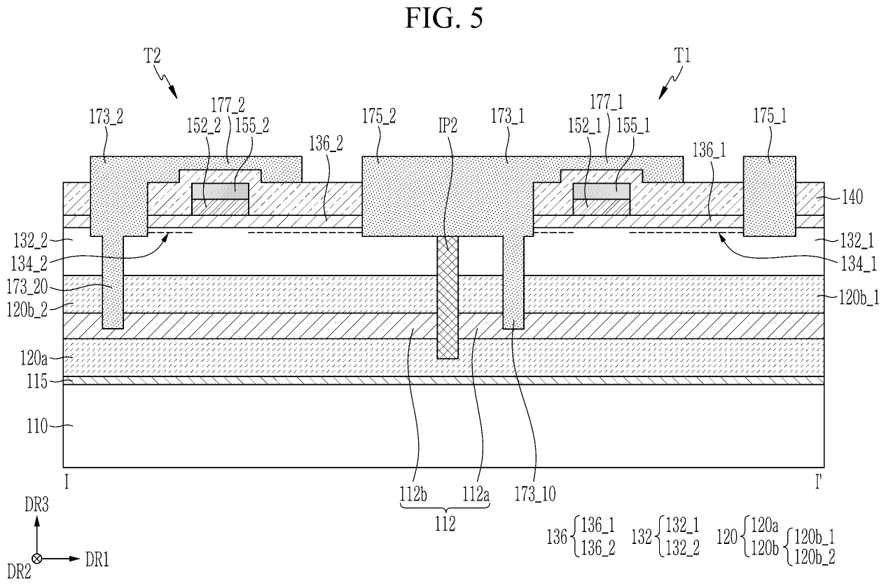

Hereinafter, a modified example of the semiconductor device according to the embodiment of FIGS. 1 to 4 will be described with reference to FIG. 5.

FIG. 5 illustrates a cross-sectional view showing an amplification circuit of a semiconductor device according to an embodiment. FIG. 5 illustrates a cross-sectional view taken along a line I-I′ of FIG. 3. Descriptions of the embodiment of FIG. 5 that overlap the embodiments of FIGS. 1 to 4 will be omitted or simplified, and differences will be mainly described.

In the embodiment of FIG. 5, as in the embodiments of FIGS. 1 to 4, the well region 112 may be positioned within the buffer layer 120. The well region 112 may include the same semiconductor material as that of the channel layer 132, and may be doped with n-type impurities. The well region 112 may include a first well region 112a and a second well region 112b that are spaced apart in a direction (e.g., first direction DR1) parallel to the upper surface of the substrate 110 by an insulating pattern IP2.

The first drain electrode 175_1 of the first transistor T1 may be connected to a first power voltage, the first source electrode 173_1 of the first transistor T1 may be connected to the second drain electrode 175_2 of the second transistor T2, and the second source electrode 173_2 of the second transistor T2 may be connected to a second power voltage. The first power voltage may be higher than the second power voltage. The first source electrode 173_1 of the first transistor T1 and the second drain electrode 175_2 of the second transistor T2 may be integrated, but the present invention is not limited thereto. The first source electrode 173_1 and the second drain electrode 175_2 may be separate components, in which case the first source electrode 173_1 and the second drain electrode 175_2 may be connected by another component.

The first transistor T1 may be positioned on the first well region 112a, and the second transistor T2 may be positioned on the second well region 112b. The first source electrode 173_1 of the first transistor T1 and the second drain electrode 175_2 of the second transistor T2 may be connected to the first well region 112a, and the second source electrode 173_2 of the second transistor T2 may be connected to the second well region 112b.

The first source electrode 173_1 may include a first contact portion 173_10 that extends through the first channel layer 132_1 and the first upper buffer layer 120b_1 to contact the first well region 112a. The second source electrode 173_2 may include a second contact portion 173_20 that extends through the second channel layer 132_2 and the second upper buffer layer 120b_2 to contact the second well region 112b.

In the embodiment of FIG. 5, the insulating pattern IP2 may extend through the channel layer 132, the upper buffer layer 120b, and the well region 112. A lower surface of the insulating pattern IP2 may be in contact with the lower buffer layer 120a, but the present invention is not necessarily limited thereto. The insulating pattern IP2 may be positioned between the first channel layer 132_1 and the second channel layer 132_2, may be positioned between the first upper buffer layer 120b_1 and the second upper buffer layer 120b_2, and may be positioned between the first well region 112a and the second well region 112b. The first channel layer 132_1 and the second channel layer 132_2 may be separated by the insulating pattern IP2. The first upper buffer layer 120b_1 and the second upper buffer layer 120b_2 may be separated by the insulating pattern IP2. The first well region 112a and the second well region 112b may be separated by the insulating pattern IP2.

In the embodiment of FIG. 5, unlike in the embodiments of FIGS. 1 to 4, the insulating pattern IP2 may not be positioned between the first barrier layer 136_1 and the second barrier layer 136_2. The insulating pattern IP2 may not be positioned between the first source electrode 173_1 and the second drain electrode 175_2. An upper surface of the insulating pattern IP2 may be in contact with the first source electrode 173_1 and the second drain electrode 175_2.

According to an embodiment, the insulating pattern IP2 may include argon (Ar) or nitrogen (N), but the present invention is not necessarily limited thereto. For example, a photoresist pattern may be positioned on the barrier layer 136 to expose a portion of the barrier layer 136, and an ion implant process may be performed to inject Ar, N, etc. into the barrier layer 136, the channel layer 132, the buffer layer 120, and the well region 112 to form the insulating pattern IP2. Thereafter, an etching process may be performed to penetrate the barrier layer 136 and to partially recess the channel layer 132 so as to form the first source electrode 173_1 and the second drain electrode 175_2 on the upper surface of the channel layer 132. In the etching process, a region where ions of the barrier layer 136 were implanted may be removed, and a region where ions of the channel layer 132 were implanted may be partially removed.

According to an embodiment, a length of the insulating pattern IP2 in the third direction DR3 may be determined depending on a depth at which ions are implanted. In FIG. 4, it is shown that ions are implanted up to a middle level of the lower buffer layer 120a, but the present invention is not limited thereto. The depth at which ions are implanted may be varied, and it may be sufficient that the ions are implanted to a lower surface of the well region 112 to separate the well region 112 into the first well region 112a and the second well region 112b. For example, the ion may be implanted up to a lower surface of the lower buffer layer 120a, up to the seed layer 115, or up to the upper surface of the substrate 110.

In addition, descriptions with reference to FIGS. 1 to 4 may be applied in the same or similar manner to descriptions of other components for which detailed descriptions have been omitted.

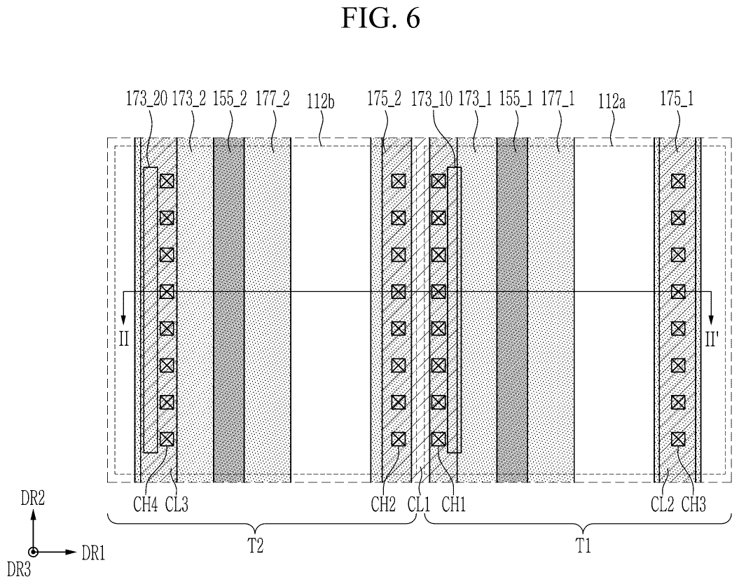

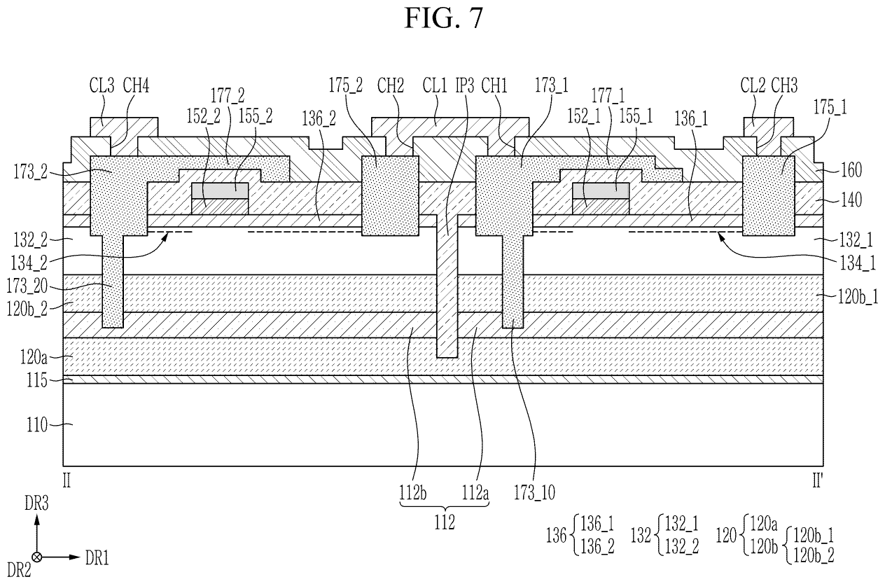

Hereinafter, a modified example of the semiconductor device according to the embodiment of FIGS. 1 to 4 will be described with reference to FIG. 6 and FIG. 7.

FIG. 6 illustrates a top plan view showing an amplification circuit of a semiconductor device according to an embodiment. FIG. 6 shows a source electrode, a drain electrode, and a gate electrode of transistors constituting an amplification circuit according to an embodiment, and remaining components are omitted. FIG. 7 illustrates a cross-sectional view taken along a line II-II′ of FIG. 6 according to an embodiment. Descriptions of the embodiment of FIG. 6 and FIG. 7 that overlap the embodiments of FIGS. 1 to 4 will be omitted or simplified and differences will be mainly described.

In the embodiments of FIG. 6 and FIG. 7, as in the embodiments of FIGS. 1 to 4, the well region 112 may be positioned within the buffer layer 120. The well region 112 may include the same semiconductor material as that of the channel layer 132, and may be doped with n-type impurities. The well region 112 may include a first well region 112a and a second well region 112b that are spaced apart in a direction (e.g., first direction DR1) parallel to the upper surface of the substrate 110 by an insulating pattern IP3.

The first drain electrode 175_1 of the first transistor T1 may be connected to a first power voltage, the first source electrode 173_1 of the first transistor T1 may be connected to the second drain electrode 17_ 2 of the second transistor T2, and the second source electrode 173_2 of the second transistor T2 may be connected to a second power voltage. The first power voltage may be higher than the second power voltage.

The first transistor T1 may be positioned on the first well region 112a, and the second transistor T2 may be positioned on the second well region 112b. The first source electrode 173_1 of the first transistor T1 and the second drain electrode 175_2 of the second transistor T2 may be connected to the first well region 112a, and the second source electrode 173_2 of the second transistor T2 may be connected to the second well region 112b.

The first source electrode 173_1 may include a first contact portion 173_10 that extends through the first channel layer 132_1 and the first upper buffer layer 120b_1 to contact the first well region 112a. The second source electrode 173_2 may include a second contact portion 173_20 that extends through the second channel layer 132_2 and the second upper buffer layer 120b_2 to contact the second well region 112b.

In the embodiment of FIGS. 6 and 7, the semiconductor device may further include a second protective layer 160 positioned on the first protective layer 140. The second protective layer 160 may be disposed on the first source electrode 173_1, the first drain electrode 175_1, the second source electrode 173_2, and the second drain electrode 175_2. The second protective layer 160 may cover the first source electrode 173_1, the first gate electrode 155_1, the first drain electrode 175_1, the second source electrode 173_2, the second gate electrode 155_2, and the second drain electrode 175_2. The second protective layer 160 may be in contact with upper and side surfaces of the first source electrode 173_1, the first field distribution layer 177_1, the first drain electrode 175_1, the second source electrode 173_2, the second field distribution layer 177_2, and the second drain electrode 175_2. The second protective layer 160 may be spaced apart from upper and side surfaces of the first gate electrode 155_1 and the second gate electrode 155_2 by the first protective layer 140. The second protective layer 160 may not be in contact with upper and side surfaces of the first gate electrode 155_1 and the second gate electrode 155_2 by the first field dispersion layer 177_1, the second field dispersion layer 177_2, and the first protective layer 140

The second protective layer 160 may include an insulating material. For example, the second protective layer 160 may include an oxide such as SiO₂ or Al₂O₃. As another example, the second protective layer 160 may include a nitride such as SiN or an acid nitride such as SiON. The second protective layer 160 may include the same material as the first protective layer 140, or may include a different material therefrom. If the first protective layer 140 and the second protective layer 160 are made of the same material, a boundary between the first protective layer 140 and the second protective layer 160 may not be visible. The second protective layer 160 may be formed as a single layer or multiple layers.

In the embodiment of FIGS. 6 and 7, unlike in the embodiments of FIGS. 1 to 4, the first source electrode 173_1 and the second drain electrode 175_2 may not be formed as a single body. For example, the first source electrode 173_1 and the second drain electrode 175_2 may be separated from each other. The first source electrode 173 1 and the second drain electrode 175_2 may be spaced apart in a direction (e.g., first direction DR1) parallel to the upper surface of the substrate 110 by the insulating pattern IP3 and the protective layers 140 and 160.

In the embodiment of FIGS. 6 and 7, the semiconductor device may further include a first connection wire CL1 extending through the second protective layer 160 positioned on the first source electrode 173_1 and the second drain electrode 175_2.

For example, a first contact hole CH1 and a second contact hole CH2 may be formed to extend through the second protective layer 160, and the first connection wire CL1 may be formed by depositing a conductive material (e.g., metal) filling insides of the first contact hole CH1 and the second contact hole CH2. The first connection wire CL1 may cover a portion of an upper surface of the second protective layer 160. The first connection wire CL1 may be connected to the first source electrode 173_1 through the first contact hole CH1 and to the second drain electrode 175_2 through the second contact hole CH2.

Referring to FIG. 6, a plurality of first contact hole CH1 and a plurality of second contact hole CH2 extending through the second protective layer 160 may be provided. For example, the first contact holes CH1 may overlap the first source electrode 173_1 in the third direction DR3, and may be arranged to be spaced apart at a predetermined interval along the second direction DR2. The second contact holes CH2 may overlap the second drain electrode 175_2 in the third direction DR3, and may be arranged to be spaced apart at a predetermined interval along the second direction DR2. The first connection wire CL1 may be connected to the first source electrode 173_1 through the first contact holes CHI and to the second drain electrode 175_2 through the second contact holes CH2.

According to an embodiment, the semiconductor device may further include a second connection wire CL2 extending through the second protective layer 160 positioned on the first drain electrode 175_1, and a third connection wire CL3 extending through the second protective layer 160 positioned on the second source electrode 173_2.

For example, a third contact hole CH3 may be formed to extend through the second protective layer 160, and the second connection wire CL2 may be formed by depositing a conductive material (e.g., metal) filling an inside of the third contact hole CH3. The second connection wire CL2 may cover a portion of an upper surface of the second protective layer 160. The second connection wire CL2 may be connected to the first drain electrode 175_1 through the third contact hole CH3. The second connection wire CL2 may be a wire connected to the first power voltage.

Referring to FIG. 6, a plurality of third contact holes CH3 extending through the second protective layer 160 may be provided. For example, the third contact holes CH3 may overlap the first drain electrode 175_1 in the third direction DR3, and may be arranged to be spaced apart at a predetermined interval along the second direction DR2. The second connection wire CL2 may be connected to the first drain electrode 175_1 through the third contact holes CH3.

For example, a fourth contact hole CH4 may be formed to extend through the second protective layer 160, and the third connection wire CL3 may be formed by depositing a conductive material (e.g., metal) filling an inside of the fourth contact hole CH4. The third connection wire CL3 may cover a portion of an upper surface of the second protective layer 160. The third connection wire CL3 may be connected to the second source electrode 173_2 through the fourth contact hole CH4. The third connection wire CL3 may be a wire connected to the second power voltage.

Referring to FIG. 6, a plurality of fourth contact holes CH4 extending through the second protective layer 160 may be provided. For example, the fourth contact holes CH4 may overlap the second source electrode 173_2 in the third direction DR3, and may be arranged to be spaced apart at a predetermined interval along the second direction DR2. The third connection wire CL3 may be connected to the second source electrode 173_2 through the fourth contact holes CH4.

According to an embodiment, the first connection wire CL1 may be positioned on the same layer as that of each of the second connection wire CL2 and the third connection wire CL3. For example, the first contact hole CH1, the second contact hole CH2, the third contact hole CH3, and the fourth contact hole CH4 may be formed together in the same process. The first connection wire CL1 may be formed together in the same process as that of each of the second connection wire CL2 and the third connection wire CL3. The first connection wire CL1 may include the same material as that of each of the second connection wire CL2 and the third connection wire CL3.

In addition, descriptions with reference to FIGS. 1 to 4 may be applied in the same or similar manner to descriptions of other components for which detailed descriptions have been omitted.

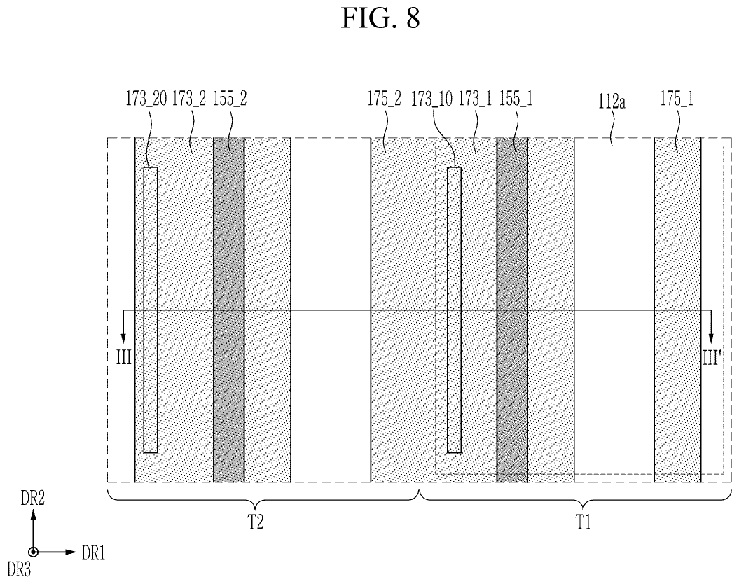

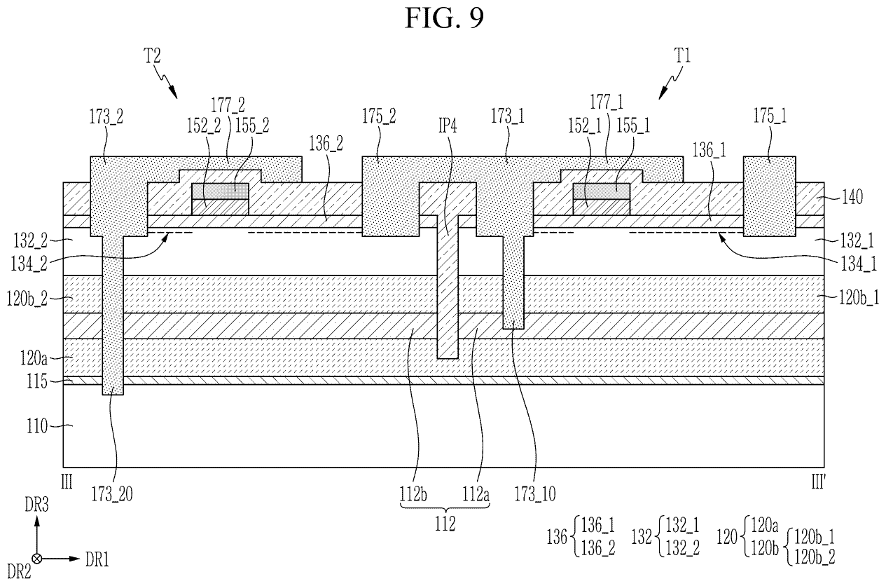

Hereinafter, a modified example of the semiconductor device according to the embodiment of FIGS. 1 to 4 will be described with reference to FIG. 8 and FIG. 9.

FIG. 8 illustrates a top plan view showing an amplification circuit of a semiconductor device according to an embodiment. FIG. 8 shows a source electrode, a drain electrode, and a gate electrode of transistors constituting an amplification circuit according to an embodiment, and remaining components are omitted. FIG. 9 illustrates a cross-sectional view taken along a line III-III′ of FIG. 8 according to an embodiment. Descriptions of the embodiment of FIG. 8 and FIG. 9 that overlap the embodiments of FIGS. 1 to 4 will be omitted or simplified and differences will be mainly described.

In the embodiment of FIG. 8 and FIG. 9, as in the embodiments of FIGS. 1 to 4, the well region 112 may be positioned within the buffer layer 120. The well region 112 may include the same semiconductor material as that of the channel layer 132, and may be doped with n-type impurities. The well region 112 may include a first well region 112a and a second well region 112b that are spaced apart in a direction (e.g., first direction DR1) parallel to the upper surface of the substrate 110 by an insulating pattern IP4.

The first drain electrode 175_1 of the first transistor T1 may be connected to a first power voltage, the first source electrode 173_1 of the first transistor T1 may be connected to the second drain electrode 175_2 of the second transistor T2, and the second source electrode 173_2 of the second transistor T2 may be connected to a second power voltage. The first power voltage may be higher than the second power voltage. The first source electrode 173_1 of the first transistor T1 and the second drain electrode 175_2 of the second transistor T2 may be integrated, but the present invention is not limited thereto. The first source electrode 173_1 and the second drain electrode 175_2 may be separate components, in which case the first source electrode 173_1 and the second drain electrode 175_2 may be connected by another component.

The first transistor T1 may be positioned on the first well region 112a, and the second transistor T2 may be positioned on the second well region 112b. The first source electrode 173_1 of the first transistor T1 may be connected to the first well region 112a, and the second source electrode 173_2 of the second transistor T2 may be connected to the second well region 112b. The first source electrode 173_1 may include a first contact portion 173_10 that extends through the first channel layer 132_1 and the first upper buffer layer 120b_1 to contact the first well region 112a.

In the embodiment of FIGS. 8 and 9, the second source electrode 173_2 may include a second contact portion 173_20 that extends through the second channel layer 132_2, the second upper buffer layer 120b_2, the second well region 112b, the lower buffer layer 120a, and the seed layer 115 in a direction perpendicular to the upper surface of the substrate 110 (e.g., third direction DR3) to contact the substrate 110. In the embodiments of FIGS. 8 and 9, unlike in the embodiments of FIGS. 1 to 4, the second contact portion 173_20 may further extend through the second well region 112b, the lower buffer layer 120a, and the seed layer 115, and may contact the substrate 110.

As shown in FIG. 9, the first well region 112a may be spaced apart from the substrate 110, the seed layer 115, and the lower buffer layer 120a, and the first well region 112a may be separated from the second well region 112b by an insulating pattern IP4. The first well region 112a may be insulated from the substrate 110 and the second well region 112b. According to an embodiment, the first contact portion 173_10 and the second contact portion 173_20 may be respectively connected to the first well region 112a and the substrate 110 that are insulated from each other.

In FIG. 9, a side surface of the second contact portion 173_20 is shown as being in contact with the second well region 112b, but the present invention is not necessarily limited thereto. For example, the semiconductor device may further include an insulating layer between the side surface of the second contact portion 173_20 and the second well region 112b. The insulating layer may cover the side surface of the second contact part 173_20, and may not cover a lower surface of the second contact portion 173_20.

While this disclosure has been described in connection with what is presently considered to be practical embodiments, it is to be understood that the invention is not limited to the disclosed embodiments, but, on the contrary, is intended to cover various modifications and equivalent dispositions included within the spirit and scope of the present invention as set forth in the appended claims.

What is claimed is:

1. A semiconductor device comprising:
a substrate;
a first transistor and a second transistor positioned on the substrate;
a buffer layer disposed between the first transistor and the substrate and between the second transistor and the substrate;
a well region positioned within the buffer layer; and
an insulating pattern extending through the well region, wherein:
the first transistor includes:
a first channel layer disposed on the substrate;
a first barrier layer disposed on the first channel layer;
a first gate electrode positioned on the first barrier layer; and
a first source electrode and a first drain electrode positioned at opposite sides of the first gate electrode and connected to the first channel layer,
the second transistor includes:
a second channel layer disposed on the substrate;
a second barrier layer disposed on the second channel layer;
a second gate electrode positioned on the second barrier layer; and
a second source electrode and a second drain electrode positioned at opposite sides of the second gate electrode and connected to the second channel layer,
the first drain electrode is connected to a first power voltage, and the second source electrode is connected to a second power voltage different from the first power voltage, and
the first source electrode and the second drain electrode are connected to the well region.

2. The semiconductor device of claim 1, wherein the well region includes the same semiconductor material as that of each of the first and second channel layers, and is doped with an n-type impurity.

3. The semiconductor device of claim 2, wherein the first power voltage is higher than the second power voltage.

4. The semiconductor device of claim 3, wherein the insulating pattern is positioned between the first channel layer and the second channel layer, between the first barrier layer and the second barrier layer, and between the first source electrode and the second drain electrode.

5. The semiconductor device of claim 3, wherein the insulating pattern is positioned between the first channel layer and the second channel layer, and
wherein the first source electrode and the second drain electrode are in contact with an upper surface of the insulating pattern.

6. The semiconductor device of claim 5, wherein the insulating pattern includes Ar or N.

7. The semiconductor device of claim 3, wherein the well region includes a first well region and a second well region spaced apart by the insulating pattern, and
wherein the first source electrode and the second drain electrode are connected to the first well region.

8. The semiconductor device of claim 7, wherein the second source electrode is connected to the second well region or connected to the substrate through the second well region.

9. The semiconductor device of claim 1, wherein the buffer layer includes a lower buffer layer and an upper buffer layer, and
wherein the well region is positioned between the lower buffer layer and the upper buffer layer.

10. The semiconductor device of claim 1, wherein the first source electrode and the second drain electrode are integrated.

11. The semiconductor device of claim 1, wherein the first source electrode is separated from the second drain electrode by the insulating pattern, and
wherein the semiconductor device further includes:
a protective layer positioned on the first source electrode, the first drain electrode, the second source electrode, and the second drain electrode and including an insulating material; and
a first connection wire that extends through the protective layer to be connected to the first source electrode and the second drain electrode.

12. The semiconductor device of claim 11, wherein the semiconductor device further includes:
a second connection wire extending through the protective layer to be connected to the first drain electrode; and
a third connection wire extending through the protective layer to be connected to the second source electrode, and
wherein the first connection wire is positioned on the same layer as that of each of the second connection wire and the third connection wire.

13. A semiconductor device comprising:
a substrate;
a buffer layer disposed on the substrate;
an insulating pattern extending through at least a portion of the buffer layer;
a first well region and a second well region positioned within the buffer layer and spaced apart by the insulating pattern; and
a first transistor positioned on the first well region and a second transistor positioned on the second well region, wherein:
the first transistor includes:
a first channel layer disposed on the substrate;
a first barrier layer disposed on the first channel layer;
a first gate electrode positioned on the first barrier layer; and
a first source electrode and a first drain electrode positioned at opposite sides of the first gate electrode and connected to the first channel layer,
the second transistor includes:
a second channel layer disposed on the substrate;
a second barrier layer disposed on the second channel layer;
a second gate electrode positioned on the second barrier layer; and
a second source electrode and a second drain electrode positioned at opposite sides of the second gate electrode and connected to the second channel layer,
the first drain electrode is connected to a first power voltage, and the second source electrode is connected to a second power voltage different from the first power voltage, and
the first source electrode and the second drain electrode are connected to the first well region.

14. The semiconductor device of claim 13, wherein each of the first well region and the second well region includes the same semiconductor material as that of each of the first channel layer and the second channel layer, and includes an n-type impurity.

15. The semiconductor device of claim 13, further comprising:
a protective layer configured to cover the first gate electrode and the second gate electrode,
wherein the insulating pattern is integrated with the protective layer.

16. The semiconductor device of claim 13, wherein the insulating pattern includes Ar or N.

17. The semiconductor device of claim 13, wherein the second source electrode is connected to the second well region or the substrate.

18. The semiconductor device of claim 13, wherein the buffer layer includes a lower buffer layer and first and second upper buffer layers,
wherein the first well region is positioned between the lower buffer layer and the first upper buffer layer, and
wherein the second well region is positioned between the lower buffer layer and the second upper buffer layer.

19. A semiconductor device comprising:
a substrate;
a first transistor and a second transistor positioned on the substrate;
a buffer layer disposed between the first transistor and the substrate and between the second transistor and the substrate;
a well region positioned within the buffer layer and including GaN doped with an n-type impurity; and
an insulating pattern extending through the well region, wherein:
the first transistor includes:
a first channel layer disposed on the substrate and including GaN;
a first barrier layer disposed on the first channel layer and including AlGaN;
a first gate electrode positioned on the first barrier layer; and
a first source electrode and a first drain electrode positioned at opposite sides of the first gate electrode and connected to the first channel layer,
the second transistor includes:
a second channel layer disposed on the substrate and including GaN;
a second barrier layer disposed on the second channel layer and including AlGaN;
a second gate electrode positioned on the second barrier layer; and
a second source electrode and a second drain electrode positioned at opposite sides of the second gate electrode and connected to the second channel layer,
the first drain electrode is connected to a first power voltage, and the second source electrode is connected to a second power voltage lower than the first power voltage, and
the first source electrode and the second drain electrode are connected to the well region.

20. The semiconductor device of claim 19, wherein the well region includes a first well region and a second well region spaced apart by the insulating pattern,
wherein the first source electrode and the second drain electrode are connected to the first well region, and
wherein the second source electrode is connected to the second well region.
